(19) United States
(12) Patent Application Publication
(10) Pub. No.: US 2011/0220596 A1
(43) Pub. Date: Sep. 15, 2011

(54) SUPPORT SYSTEM FOR SOLAR PANELS

(75) Inventors: Paul R. Cusson, West Hartford, CT (US); Thomas P. Kilar, JR., Boardman, OH (US); Robert J. Voytilla, Hubbard, OH (US); Charles Blackman, Leetonia, OH (US); Michael G. Greenamyer, Salem, OH (US)

(73) Assignee: Northern States Metals Company, West Hartford, CT (US)

(21) Appl. No.: 13/115,506

(22) Filed: May 25, 2011

Related U.S. Application Data
(63) Continuation-in-part of application No. 12/686,598, filed on Jan. 13, 2010.
Application No. 12/686,598 is a continuation-in-part of application No. 12/567,908, filed on Sep. 28, 2009.
Application No. 12/567,908 is a continuation-in-part of application No. 12/383,240, filed on Mar. 20, 2009.
(60) Provisional application No. 61/397,113, filed on Jun. 7, 2010.
(60) Provisional application No. 61/414,963, filed on Nov. 18, 2010.

(51) Int. Cl. H01L 23/32; F16B 2/02; F16L 3/08; H05K 7/02; H05K 13/00

(52) U.S. Cl. 211/41.1; 24/522; 361/679.01; 29/825

(57) ABSTRACT

A panel support and wiring system is used as part of a bi-directional solar panel support matrix having lower support joists and upper panel rails. Both the panel clip and wiring arrangements are configured to facilitate rapid deployment and installation of the entire solar panel system, including supports and interfaces with the underlying substrate. A standardized wiring system is one of the factors facilitating rapid installation.

### PRIORITY INFORMATION

The present application claims priority as a continuation-in-part application from U.S. patent application Ser. No. 12/686,598, filed Jan. 13, 2010, which is a continuation-in-part application from U.S. patent application Ser. No. 12/567,908 filed on Sep. 28, 2009, which is a continuation-in-part application from parent U.S. patent application Ser. No. 12/383,240 filed on Mar. 20, 2009, U.S. Provisional Application 61/397,113 filed on Jun. 7, 2010, and U.S. Provisional Application 61/414,963 filed on Nov. 18, 2010. Reference is made to all listed applications, and their contents are incorporated herein in their entirety.

### FIELD OF THE INVENTION

This invention relates in general to support systems for panels and panel-like structures, such as solar energy collection systems. More particularly, the present invention is directed to a support and wiring system for an array of photovoltaic panels, and a method of assembling the same for activation. The support system is a bi-directional matrix including a variety of profiled panel rails arranged for attachment to a variety of panel configurations. A variety of wiring devices and panel rail wiring configurations may also be used.

### BACKGROUND OF THE INVENTION

A standard photovoltaic (solar) panel array includes a plurality of solar panels optimally arranged for converting light incident upon the panels to electricity. Various support systems are used for attachment to roofs, free-field ground racks or tracking units. Typically, these support systems are costly, labor intensive to install, heavy, structurally inferior, and mechanically complicated. Placing the solar panels on the support structure can be very difficult, as can wiring of the solar panels for array activation. Further, some large solar panels tend to sag and flex thereby rendering the panel mounting unstable. Unstable panel arrangements also jeopardize the integrity of the wiring arrangement, which is necessary for the photovoltaic panels to be useful.

A conventional panel support system generally includes off-the-shelf metal framing channels having a C-shaped cross-section, such as those sold under the trademarks UNISTRUT™ BLIME™, improvised for use as vertical and horizontal support members. The photovoltaic (solar) panels 12 or other panel-like structures are directly secured to the support members and held in place by panel clips or panel holders (100, 100′, 120, 145) in a wide range of sizes and shapes. The panel clips serve as hold-down devices to secure the panel against the corresponding top support member in spaced-relationship. The clips are positioned and attached about the panel edges once each panel is arranged in place.

For a conventional free-field ground rack system (for mounting solar panels) as shown in FIG. 1, vertical support elements, such as I-beams 14, are spaced and securely embedded vertically in the ground. Tilt mounting brackets 16, are installed at the top of each I-beam, and each tilt mounting bracket is secured to the I-beam such that a tilt bracket flange extends above the I-beam at an angle as best seen in FIG. 2A. As shown in this case, two UNISTRUT™ joists 13 span the tilt mounting brackets 16 and are secured thereto. As seen in FIG. 2B, UNISTRUT™ upper panel rails 15 are positioned across and fastened to the lower support joists 13. To secure each upper panel rail to the corresponding lower support joists, a bolt through a bolt hole made in the rail sidewall attaches to a threaded opening in a transverse nut-like plate slideably mounted inside the channel of the UNISTRUT™ rail, so that the nut-like plate engages and tightly secures against the upper flange of the joist's C-channel 11 as seen in FIG. 2A. Importantly, the width of the plate is slightly less than the width of the channel, so that the plate can be slideably adjusted in the channel, without the plate rotating therein.

Once the bi-directional support system 10 is assembled, each solar panel 12 is mounted on a portion of panel holding clips (100, 100′, 120, 145) which are secured to the support rails about the perimeter of each panel. The other portion of the panel clips is put in place, and tightened. This installation process is usually inaccurate, and time-consuming, even with expensive, skilled installers.

Another example of a support system is shown in U.S. Pat. No. 5,762,720, issued to Hanoka et al., which describes various mounting brackets used with a UNISTRUT™ channel. Notably, the Hanoka et al. patent uses a solar cell module having an integral mounting structure, i.e. a mounting bracket bonded directly to a surface of the backskin layer of a laminated solar cell module, which is then secured to the channel bracket by bolt or slideably engaging C-shaped members. Other examples are shown in U.S. Pat. No. 6,617,507, issued to Mapes et al., U.S. Pat. No. 6,370,828, issued to Genschorek, U.S. Pat. No. 4,966,631, issued to Matlin et al., and U.S. Pat. No. 7,012,188, issued to Erling. All of these examples of conventional systems are incorporated herein by reference as background.

Notably, existing support systems require meticulous on-site assembly of multiple parts, performed by expensive, dedicated, field labor. Assembly is often performed in unfavorable working conditions, i.e. in harsh weather and over-difficult terrain, without the benefit of quality control safeguards and precision tooling. Misalignment of the overall support assembly often occurs. This can jeopardize the supported solar panels 12, or other supported devices. Further, wiring of the solar panels, once secured, is also problematic in conventional systems.

Spacing of the photovoltaic (solar) panels 12 is important to accommodate expansion and contraction due to the change in weather. It is also important that the panels are properly spaced for maximum use of the bi-directional area of the span. Different spacing may be required on account of different temperature swings within various geographical areas. It is difficult, however, to precisely space the panels on-site using existing support structures without advanced (and expensive) technical assistance.

For example, with one of the existing designs described above (with reference to FIGS. 2A and 2B), until the upper panel rails are tightly secured to the lower support joist, each rail is free to slide along the lower support joists and, therefore, will need to be properly spaced and secured once mounted on-site. Further, since the distance between the two support joists is fixed on account of the drilled bolt holes through the rails, it is preferred to drill the holes on-site, so that the lower support joists can be aligned to attach through the pre-drilled attachment holes of the tilt bracket. Unfortunately, the operation of drilling the holes on-site requires skilled workers, and even with skilled installation, might still result in misalignment of the support structure and/or the solar panels supported by that structure.

Misalignment difficulties are exacerbated by the flexing of the panels 12, and the sagging permitted by the flexibility of the panels. The sagging of the panels can cause the panels to work out of their holders, whether they would be holding clips or part of the overall structure of the upper support rail. Improper installation, which occurs frequently in conventional systems, can lead to dislocation of the panels due to sagging or atmospheric conditions. A wide variety of different mounting positions and array arrangements also exacerbate the stability problems caused by panel sagging or deflection. Further, certain mounting positions will make the panels more vulnerable to atmospheric disruptions, such as those created by wind and precipitation. Freeze-thaw cycles can also be a major factor. All of these variables further complicate electrical connections in the panel array.

The vertical support beam and tilt-mounting bracket (14, 16, as depicted in FIGS. 1 through 4B) is not the only manner in which an array of solar panels, or other panel-like structures can be mounted. This support arrangement is not always available. Rather, there are many framing substrates and support systems upon which solar panels or other panel-like structures can be mounted. For example, the roofs of many structures may not be capable of supporting the vertical support structure 14 upon which tilt mounting brackets 16 rest, but such roofs might support the panels array 10 alone.

This is particularly crucial since in many locations a roof or roof-like structure is the only support substrate that would be available for solar panels. While the vertical support and tilt mounting bracket arrangement 14, 16 include well-known load parameters, the same is not true of roofs or roof-like structures. These can exhibit a wide variety of different support parameters, as well as other characteristics. Many roof-like substrates that are used to support solar cell arrays tend to be flat (providing a level of predictability not found in the use of sloped, i.e. pitched roofs as panel array substrates). Flat roofs are preferred since they avoid the substantial problems of sloped roof mountings.

Even a stable flat roof presents problems for the mounting of an array of solar panels. In particular, the panels cannot be mounted in the same manner that is provided in FIGS. 1 through 4B of the present application. The stresses that are allowable on a roof structure are far different from those that can be applied to the vertical support beam and tilt mounting bracket (14, 16) arrangement of FIGS. 1 through 4B. As a result, a whole new set of considerations apply. Foremost among these considerations is the necessity to avoid any damage to the roof while securing panel arrays that can become quite elaborate.

Flat roofs, while serving as preferred surfaces for solar panels, are also particularly susceptible to damage since even slight indentations caused by the stresses inherent to installing a heavy panel array 10, may cause water to pool on parts of the roof, thereby compromising the integrity of the roof. To limit stresses applied to the roof by the panel array installation process, it is necessary that installing the array be as simple as possible. Likewise, wiring of the array must be as simple as possible. Otherwise, the increased activity of installation becomes detrimental to the flat roof structure. Unfortunately, wiring arrangements tend to change with the types of panels and panel configurations being deployed. This causes a lack of predictability, which keeps installers on the roof structures for extended periods of time, thereby applying increased stress to flat roofs.

Therefore, a need exists for a low-cost, uncomplicated, structurally strong support system and assembly method, so as to optimally position and easily attach a plurality of photovoltaic panels, while meeting architectural and engineering requirements. Likewise, there is an urgent need for a system that will maintain the security of the mechanical connections of the solar panels to panel rails despite the flexing of the panels (and support structure) caused by gravity, vibration, or environmental factors.

At present, none of the conventional art offers these capabilities. An improved support system would achieve a precise configuration in the field without extensive work at the installation site. The use of such an improved system would facilitate easy placement of solar panels onto the support structure. Further, a variety of different panel clips or holders could be used within the overall concept of the system. The shipping configuration of the improved support system would be such so as to be easily handled in transit while still facilitating rapid deployment. Rapid deployment must be facilitated on a roof or roof-like structure, providing stable support for the panels without damaging or otherwise compromising the roof, or any similar substrate. Rapid deployment would also include rapid mechanical connection of the panels to panel support rails in a manner that would keep the panels secure despite panel flexing due to any number of factors. Facilitation of rapid and secure wiring would also be a key part to such a system.

### SUMMARY OF THE INVENTION

It is a primary object of the present invention to improve upon conventional photovoltaic solar panel systems, especially with regard to assembly, wiring, and overall installation.

It is another object of the present invention to provide a support and installation system for solar panels in which the panels and installation site are less likely to be damaged during installation.

It is a further object of the present invention to provide a support system for solar panels that is easily installed on-site while still resulting in a precise configuration for purposes of mounting the solar panels.

It is an additional object of the present invention to provide a solar panel support system that can be assembled very quickly on-site.

It is still another object of the present invention to provide a solar panel support system that can achieve close tolerances during field installation without the necessity of skilled labor at the installation site.

It is again a further object of the present invention to provide a solar panel support system in which specialized mounting brackets bonded to the solar panels are not necessary for the mounting of the solar panels to the support system.

It is still an additional object of the present invention to provide a solar panel support system which can be easily adapted to a wide variety of solar panel array sizes and shapes.

It is yet another object of the present invention to provide a solar panel support system which minimizes the necessity for precise measurements at the installation site during installation.

It is again a further object of the present invention to provide a solar panel support system that can be arranged at a variety of different positions and configurations.

It is still an additional object of the present invention to provide a solar panel support system that can be precisely configured to a specific environment, such as a building roof.

It is another object of the present invention to provide a support system for solar panels and other panel-like structures in which degradation caused by metal-to-metal contact is substantially reduced.

It is again another object of the present invention to provide a support system for panel-like structures in which accommodation is made for movement caused by changes in temperatures, humidity or other environmental considerations.

It is still a further object of the present invention to provide a framework for a solar panel array, for use with a wide variety of roof configurations.

It is again another object of the present invention to provide a flexible arrangement for interfacing a solar panel support system to a roof or other similar substrate in order to accommodate a wide variety of different panel configurations.

It is still an additional object of the present invention to provide a solar panel mounting system that can accommodate easy installation and removal of panels on adjacent frameworks.

It is still a further object of the present invention to provide a folding solar panel support system in which rotation of structural members with respect to each other can be advantageously controlled.

It is yet an additional object of the present invention to provide a folding solar panel support system adapted specifically for roofs and roof-like substrates.

It is yet another object of the present invention to provide panel clips for a solar panel support structure which allow easy installation of adjacent panel support systems, without interfering with previously installed panels.

It is still an additional object of the present invention to provide a collapsible panel support system wherein deployment of the support system using rotating connection members can be precisely adjusted.

It is yet a further object of the present invention to provide a panel support structure which integrates easily in a wide range of mounting sites and has a minimum mounting or deployment time.

It is still another object of the present invention to provide panel clips or holders for a panel support system wherein a wide variety of different sizes and shapes of panel configurations can be accommodated, and easily installed, as well as removed.

It is again a further object of the present invention to provide a panel support system which can easily be attached to substrate support brackets without incurring damage to any of the members of the support system.

It is still another object of the present invention to provide a support system for panels or panel-like structures for a wide range of uses, positions, structures, and configurations.

It is again an additional object of the present invention to provide a panel support system in which the relative rotation of the structural members to each other when deploying the support system is carefully calibrated and controlled without adjusting or tightening at the installation site.

It is still another object of the present invention to provide a panel support system which can be easily fixed to a “hard” mounting system using bolts, without causing damage to the panel support system.

It is yet another object of the present invention to provide a panel support system that can be easily deployed or removed by rotating intersecting structural members, without fouling or jamming the rotation devices at the intersections of the structural members.

It is still a further object of the present invention to provide a panel mounting system which is entirely self-contained.

It is again an additional object of the present invention to provide a panel mounting system which facilitates quick, secure mounting of the panels once the support system is deployed.

It is yet another object of the present invention to provide a panel support system that can accommodate flexing, sagging and other deformation of the panels while maintaining a secure connection thereto.

It is yet a further object of the present invention to provide a panel mounting system which facilitates easy electrical connections to the panels.

It is again an additional object of the present invention to provide a panel mounting system that facilitates protection of the electrical wires running from the panels mounted thereon.

It is yet another object of the present invention to provide a panel clip or connector that can accommodate for flexing of both the panel and the support system.

It is still a further object of the present invention to provide a panel connection system that can facilitate rapid installation while maintaining a secure hold on the panels or panel like structures.

It is yet an additional object of the present invention to provide panel rails configured to ensure secure panel connections.

It is still a further object of the present invention to provide a gasket or liner configuration of sufficient flexibility to accommodate a wide range of different panel clips or holders.

It is yet an additional object of the present invention to provide a panel rail that facilitates protection of long cable runs.

It is still a further object of the present invention to provide wire holders that can be placed in a wide range of locations on a panel support rail so as to facilitate both temporary and permanent placement of the wires on a panel array supported by the panel rail.

It is again another object of the present invention to provide a solar panel array with a predictable, common wiring system applicable to a wide array of different panel types and configurations.

It is still an additional object of the present invention to provide a panel support system in which panels can be easily mounted from above the panel array, without diminishing the structural integrity of the panel mounting.

It is the overall goal of the present invention to provide a comprehensive panel mounting system that facilitates rapid, secure installation, including deployment of the panel support structure, placement of the panels on that support structure, and wiring of the panels for activation.

These and other goals and objects of the present invention are provided by a wiring and panel support system in a bi-directional solar panel support matrix having lower support joists and upper panel rails. Each of the upper panel rails includes an upper panel support portion and a lower wiring portion. The wiring portion is so configured to remain the same even though the upper panel clip portion varies for a plurality of different panels and panel clip arrangements.

Another embodiment of the present invention includes a wiring system in a bi-directional solar panel support matrix, having lower support joists and upper panel rails. The upper panel rails include an upper panel support portion and a lower wiring portion. Each of the lower wiring portions includes a lower support structure interfacing with an upper surface of a corresponding lower support joist. The lower wiring portion also includes a central connecting wall bridging the lower support structure and the upper panel support portion. Further included is a sidewall extending from the lower support structure to the upper panel support portion to define a cable channel with the central connecting wall.

An additional embodiment of the present invention is manifested by a method of wiring a solar panel array supported by a bi-directional support matrix having lower support joists and upper panel rails arranged to hold the solar panels. The upper panel rails have a set of first sidewalls that form a first interior space, the upper panel rails also have a connecting wall and a second sidewall to form a second interior space. The wiring method includes the steps of placing at least one electrical lead from a solar panel into at least the second interior space. Next, an electrical cable is extended along a length of the upper panel in the second interior space. Finally, the electrical lead is connected to the cable.

A further embodiment of the present invention is found in a bi-directional solar panel support matrix, having lower support joists and upper panel rails. The upper panel rails include a lower wiring section having at least one tubular structure, and an upper panel support portion having a second tubular structure having at least one surface arranged to support a solar panel.

Yet another embodiment of the present invention is found in a panel clip configured to hold a panel to an upper panel rail in a bi-directional panel support array. The panel clip is constituted by a hollow tubular support structure arranged to be attached to the panel rail. At least one upper holding structure of the panel clip is spaced from an upper surface of the panel rail on which the panel clip is mounted so that a panel can fit between the upper holding structure and the upper surface of the panel rail.

Another embodiment of the present invention is found in a wiring and panel support system in a bi-directional solar panel support matrix, having lower support joists and upper panel rails, as well as a wiring holding system. The wiring holding system includes a T-shaped connection channel formed into a bottom surface of the panel rail. Also included in the system is a wiring clip having a connection portion configured to fit into the T-shaped channel.

### BRIEF DESCRIPTION OF THE DRAWINGS

Having generally described the nature of the invention, reference will now be made to the accompanying drawings used to illustrate and describe the preferred embodiments thereof. Further, the aforementioned advantages and others will become apparent to those skilled in this art from the following detailed description of the preferred embodiments when considered in light of these drawings, in which:

FIG. 1 is a perspective view of an assembled conventional field ground rack support system for securing a plurality of solar panels;

FIG. 2A is a side view of a conventional tilt bracket mount with prior art C-shaped sectional channels secured back-to-back to form support joists to which upper panel rails, also shown in FIG. 2B, are secured;

FIG. 2B shows an end view of prior art upper panel rails, each with a C-shaped sectional channel;

FIG. 3 is a perspective view of a previously-disclosed inventive support system in a configuration as used with the instant invention showing solar panels arranged in a column and in spaced relationship thereon wherein the support system has horizontally-aligned lower support joists and (relative thereto) vertically-aligned upper panel rails;

FIG. 4A is a top plan view of the bi-directional span of the assembly as used in the instant invention, in the open position showing vertically-aligned upper panel rails attached atop horizontally-aligned lower support joists;

FIG. 4B is an end elevational view of the bi-directional span of the assembly shown in FIG. 4A;

FIG. 5A is a top view illustrating the bi-directional support frame of the assembly shown in FIG. 4A collapsed to an intermediate semi-folded position;

FIG. 5B shows in enlarged detail the support system in a collapsed or folded position, and depicting, in particular, a connector for holding the lower support joist to a support and/or tilt bracket or similar structure, i.e. held between adjacent, folded panel rails;

FIG. 5C is a side view of FIG. 5B depicting the connector for holding the lower support joist to the support and/or tilt bracket or similar structure;

FIG. 6 is a side elevation and partial sectional view depicting a typical lower support joist and a typical upper panel rail with a single-panel clip;

FIG. 7 is an end elevation and partial sectional view perpendicular to that shown in FIG. 6;

FIG. 8 is an end sectional view of one embodiment of an upper panel rail of the present invention;

FIG. 9 is an end sectional view of a second embodiment of an upper panel rail of the present invention;

FIG. 10 is an end sectional view of still another embodiment of another upper panel rail of the present invention;

FIG. 11A is an end view of a cable trough as used with the supports of the present support array;

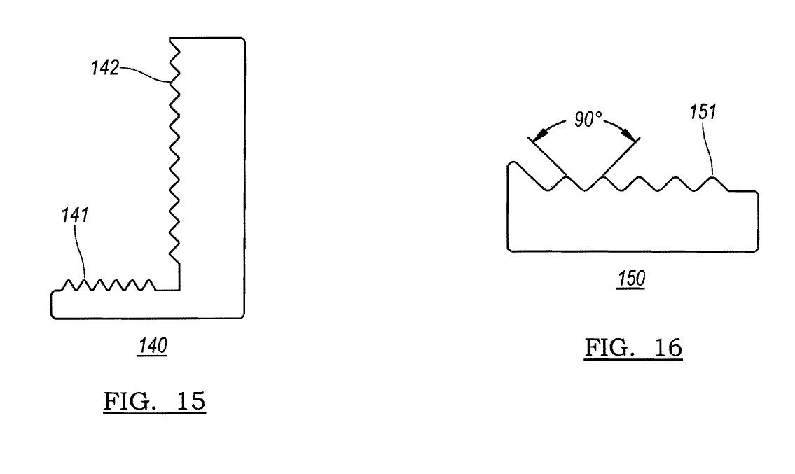

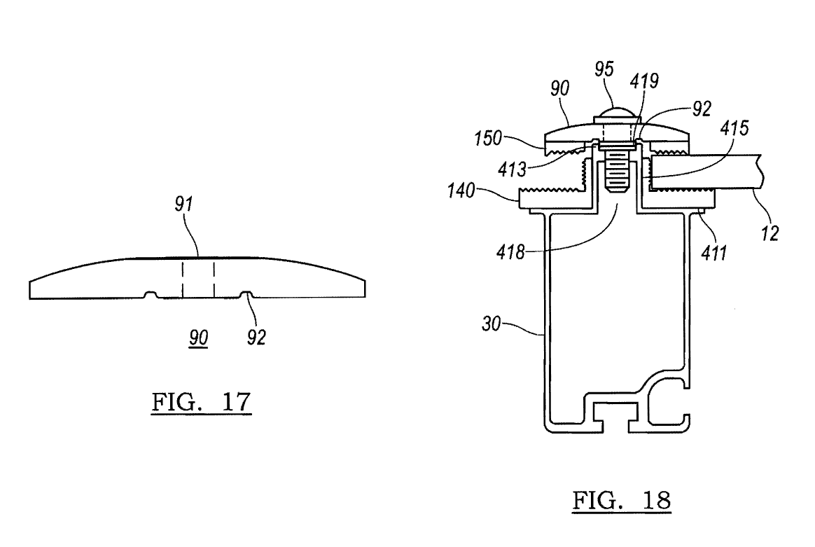

FIG. 10B is a top plan view of a support array in which the cable trough of FIG. 11A is installed;

FIG. 11C is a front view of the array of FIG. 11B;

FIG. 12A is a front view of a wire holder;

FIG. 12B is a side view of FIG. 12B;

FIG. 12C is a top view of the wire holder of FIG. 12A;

FIG. 13A is a front view of a panel holder configured for only a single panel;

FIG. 13B is a top view of the panel holder of FIG. 13A;

FIG. 13C is a front view of the panel holder of FIG. 13A arranged with a U-shaped gasket configuration;

FIG. 14A is a front view of a panel holder configured for two panels;

FIG. 14B is a top view of FIG. 14A;

FIG. 14C is a front view of the panel holder of FIG. 14A arranged with U-shaped gaskets;

FIG. 15 is a side view of an L-shaped gasket;

FIG. 16 is a side view of a straight gasket;

FIG. 17 is a side view of a panel-holding cap used in a novel configuration of an upper support rail; and

FIG. 18 is an end sectional view of an upper panel rail having a novel panel-holding cap.

### DESCRIPTION OF THE PREFERRED EMBODIMENTS

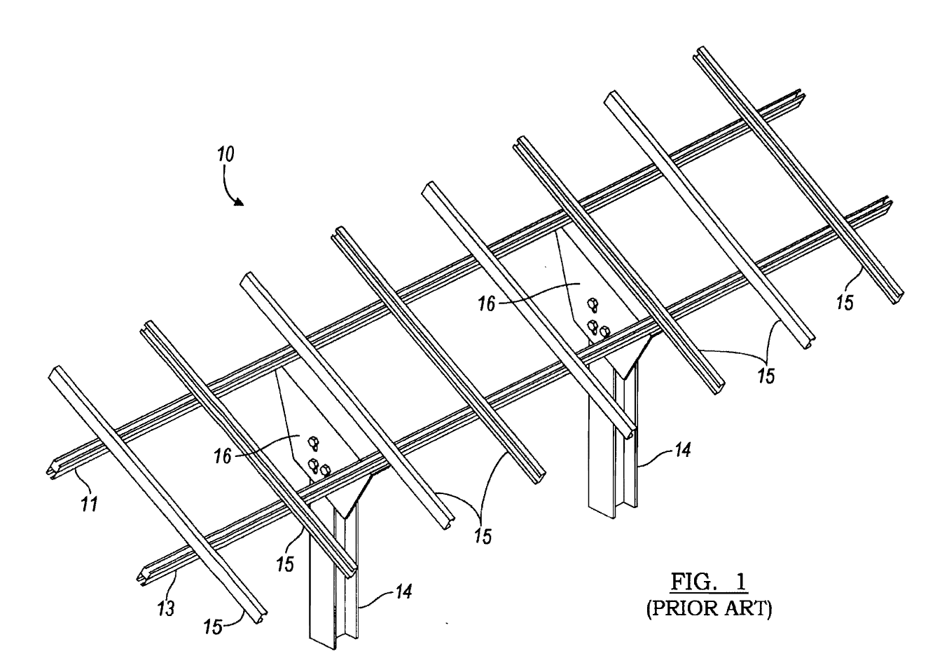

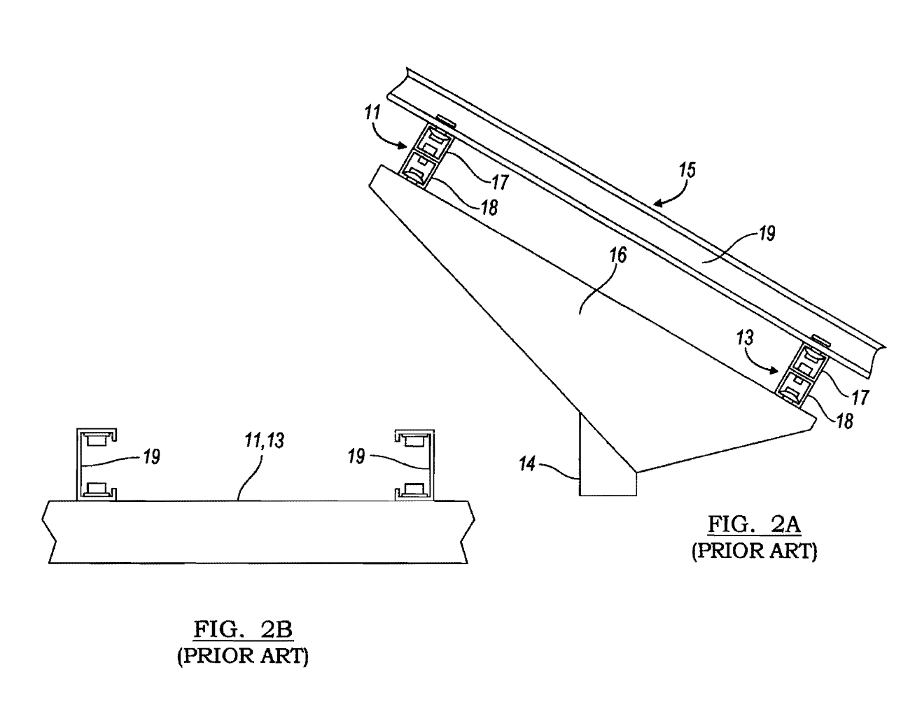

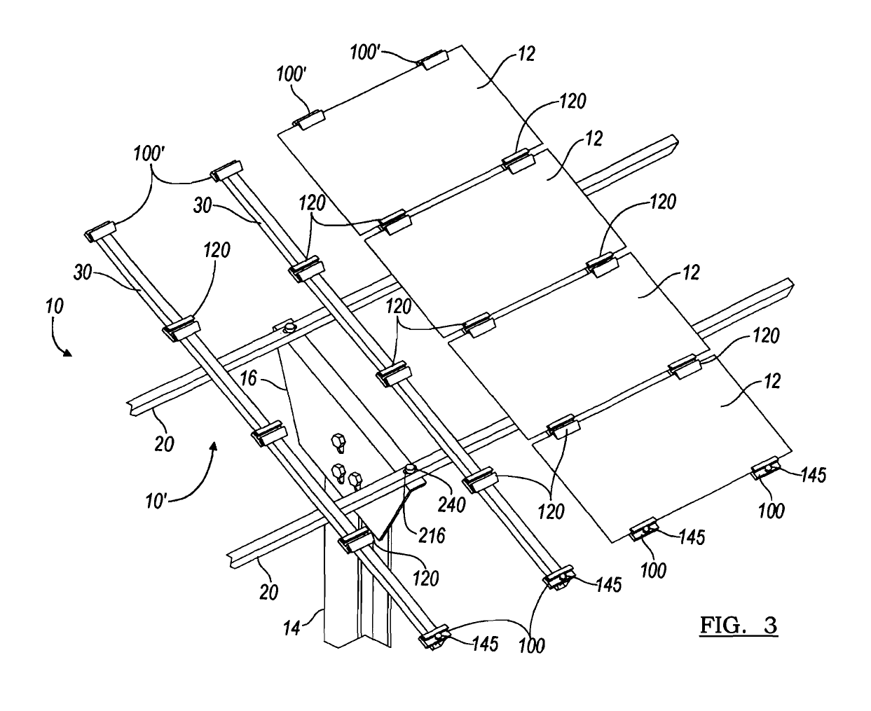

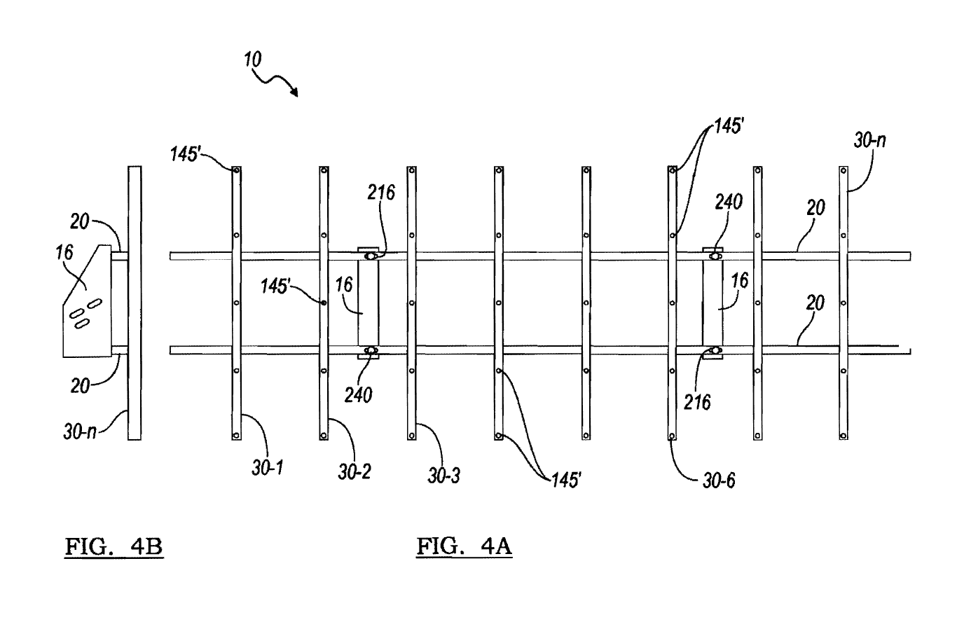

The present invention is used in the conventional environment depicted in FIGS. 1-2B, and is an improvement upon the previously disclosed inventions depicted in FIGS. 3-7. The previously disclosed inventions by the same inventors are found in U.S. patent application Ser. No. 12/383,240 (filed Mar. 20, 2009); U.S. patent Ser. No. 12/567,908 (filed Sep. 23, 2009); and, Ser. No. 12/686,598 (filed Jan. 13, 2010). All of these patent applications describe the inventions. The present patent application relies on all three for priority, and incorporates all by reference for purposes of providing a more complete background for the instant invention.

FIGS. 3-7 are relied upon as disclosing the bi-directional panel support matrix environment in which the improvements of the present application operate. Only a summary of the structures depicted in FIGS. 3-7 is provided herein, sufficient for an understanding of the background of the present invention. Full, detailed descriptions of the structures depicted in FIGS. 3-7 are found in the aforementioned, incorporated applications.

Before proceeding with further description herein, for purposes of fully appreciating the present disclosure of the instant invention, the terminology “horizontally-aligned” refers to structural members that appear to be parallel to the horizon. “Vertically-aligned” structural members are perpendicular to the “horizontally-aligned” structural members. However, because the present invention can be mounted on almost any structural support, in a variety of configurations and orientations, the terms “horizontally-aligned” and “vertically-aligned” may not best describe certain situations. Accordingly, alternative terminology such as, “longitudinally extending” or “laterally extending” may be used. For example, in FIG. 3, the “horizontally-aligned” structural members are also extended longitudinally while the “vertically-aligned” members extend in a lateral direction. These various terminologies may be used interchangeably as a matter of convenience, and to facilitate easy understanding.

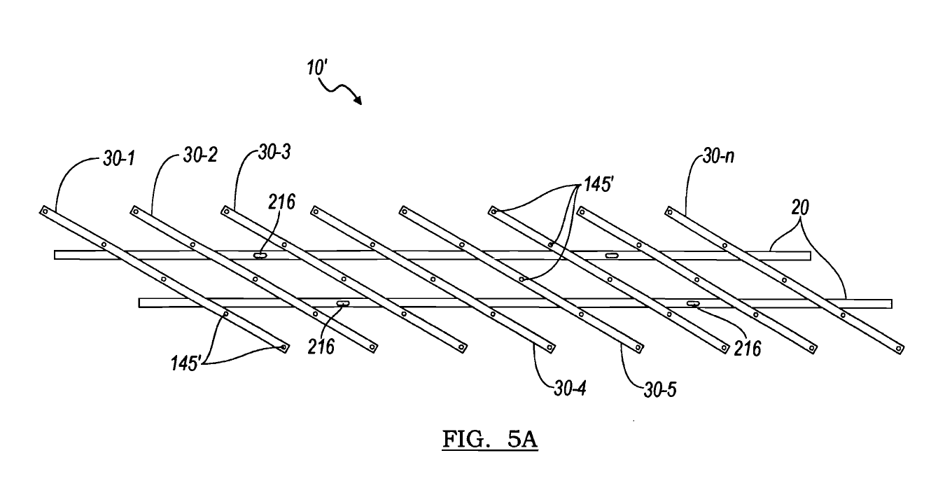

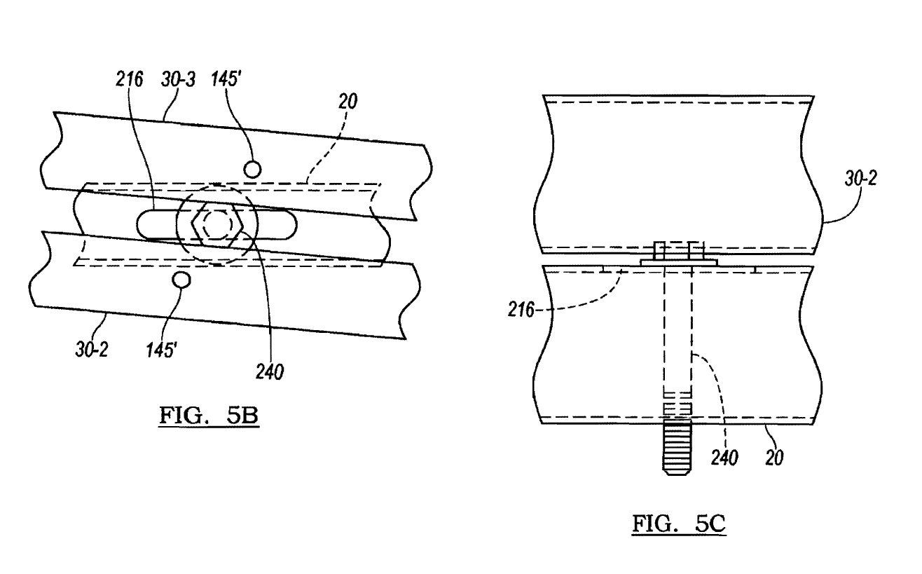

A summary of certain aspects of the previous inventions incorporated herein by reference is provided below. In accordance with one previously described inventive embodiment constituting the background of which the present invention is an improvement, FIG. 3 depicts a support system (10, 10′) for a photovoltaic array of solar panels 12, attached to a conventional, free-field vertical support arrangement (14, 16), including mounting elements. The support system 10 includes a bi-directional support frame of horizontally-aligned lower support joists 20 and vertically-aligned upper panel rails 30 (30-l through 30-n), as also seen in FIGS. 4A and 4B.

For purposes of convenience when describing the new embodiments of the present invention, the orientation description of upper and lower will be used. While an array of support system 10 can be placed in any orientation with respect to longitudinal or latitudinal descriptors, the present invention always has lower support joists 20, and upper panel rails 30. The designation of upper and lower appears to be the most straight-forward for dealing with the aspects of the new invention considered herein. The terminology “support joist” has been used previously with regard to structural members 11, 13. The same type of structural member is used as lower support joist 20 in the descriptions of the present inventive embodiments. The upper structural member, previously denoted as an upper support rail 15, is more accurately described by the designation “upper panel rail”, and designated 30 in the present embodiments. This is appropriate since the structural element 30, denoted as an upper panel rail 30 is always located above lower support joist 20, and constitutes the elements to which the external solar panels are held to the support system 10.

As an alternative to the first basic support system 10, described above, the bi-directional support system 10 can have the lower support joists 20 aligned along the length of tilting support brackets 16. As a result, upper panel rails 30 extend longitudinally, as described and depicted in the subject previous applications. It should be understood that within the context of the present invention, either orientation in any configuration of the substantially perpendicular structural elements (lower support joists 20 and upper support rails 30) can be used. Further, a wide variety of different shapes, sizes and configurations are encompassed by the concept of the present invention and is not to be limited by the examples provided herein. The present array of support members (20, 30) can be adjusted to conform to any support structure or any “footprint” available for the deployment of solar panels 12, or any other panel-like structure to be supported by the present invention. Further, as described infra, the upper panel rails 30 can be modified.

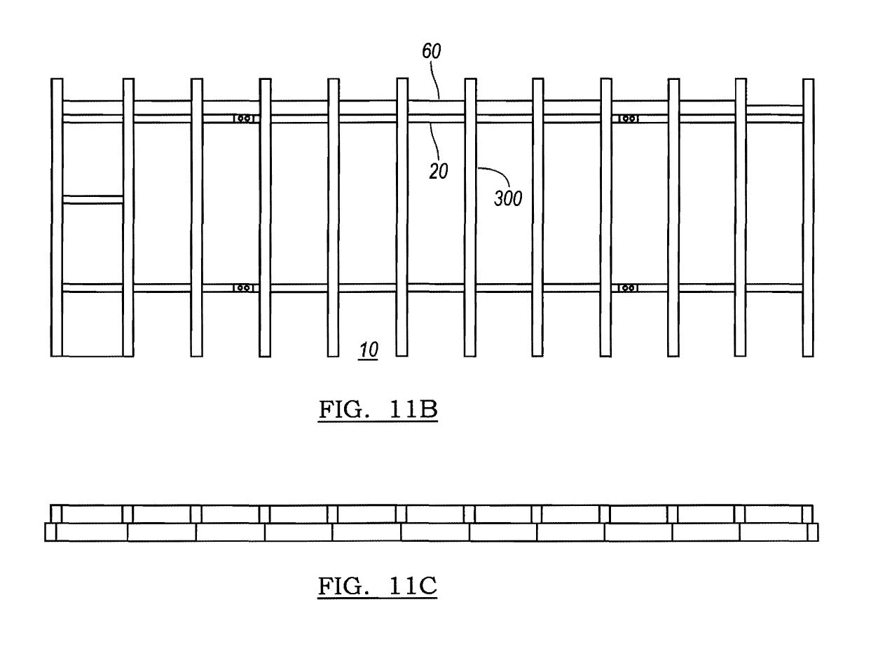

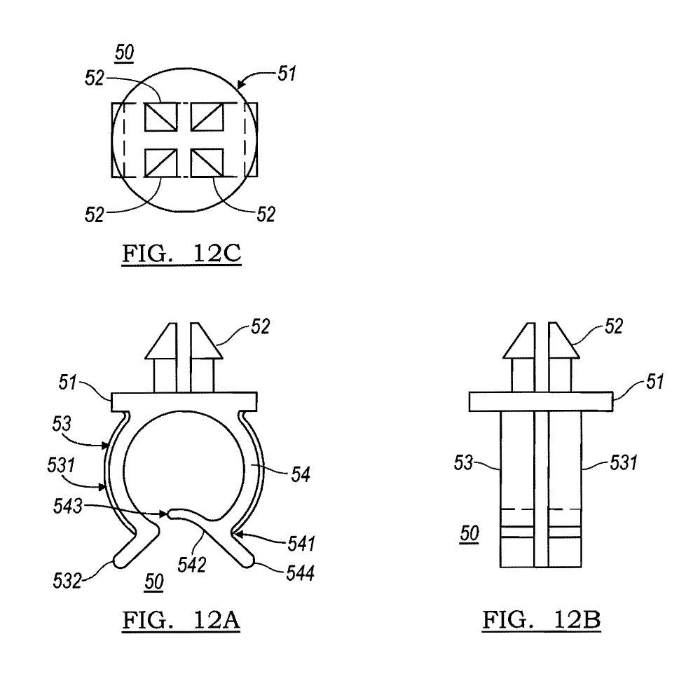

Each upper panel rail 30 in this previous design includes a hollow aluminum extrusion, as depicted in FIGS. 6 and 7. However, in the alternative, the upper panel rail may be made of roll-formed steel. In one embodiment, each panel rail 30 has a tubular body 31 having a generally rectangular cross-section with an upper wall section 36 and lower wall section 32 defined between spaced sidewalls 35 as depicted in the previous applications incorporated by reference. The upper wall section 36 has a flat top surface 37 and upper wall of varied thickness, preferably having its thickest portion 38 in the center. This thicker center portion 38 is for added strength when fastening the single-panel clips 100, 100′ and two-panel clip 120 (described below). Strength can also be achieved for each upper panel rail 30-n using a thicker lower wall section 32. The lower wall section 32 includes a longitudinal T-slot sectional channel 33 and, preferably, a longitudinal C-slot sectional channel 34. This is modified in accordance with the present invention, as described infra.

Pockets 114 (as depicted in FIGS. 6 and 7), and any clips or gaskets 130 held therein, are especially important in that they can be configured to allow the panel 12 (whether framed or unframed) to easily slide therethrough along its length. This capability allows solar panels 12 or panel-like structures to be slid along the lengths of the upper panel rails 30, thereby facilitating a quick and accurate installation of the panels supported by the inventive structural support system. The quick and accurate installation of the solar panels 12 is one of the byproducts, and is a benefit coextensive with the other benefits of the present invention (i.e. with the present invention, accuracy and security are not sacrificed for ease of installation).

The spacing between each upper panel rail 30 is governed by the width of the individual solar panels 12, and the number of solar panels per row. Each upper panel rail 30-l through 30-n, as the case may be, is attached to the lower support joists 20 by bolts 40, wherein the head 42 of each bolt is slideably accommodated in the corresponding T-slot channel 33 of the respective upper support rail. The shank 43 of the bolt 40 passes through and is secured to the respective support joist 20 using a nut 45 or other type fastener to form the bi-directional span.

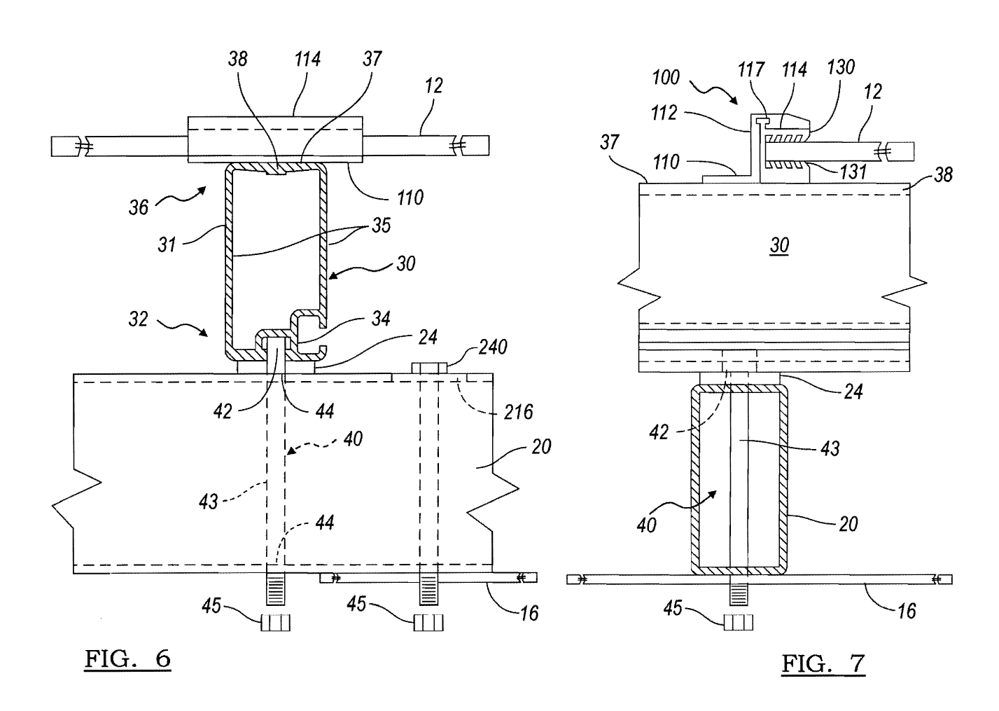

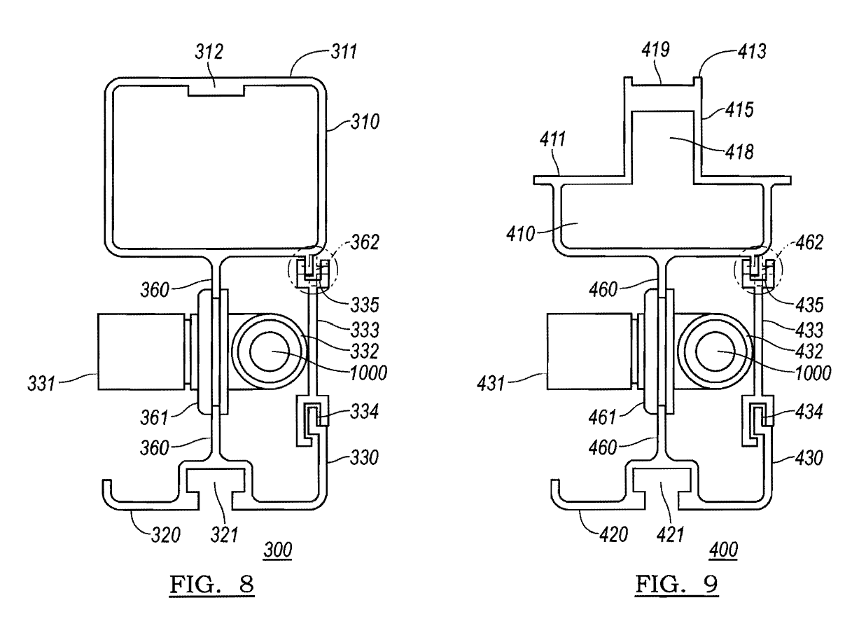

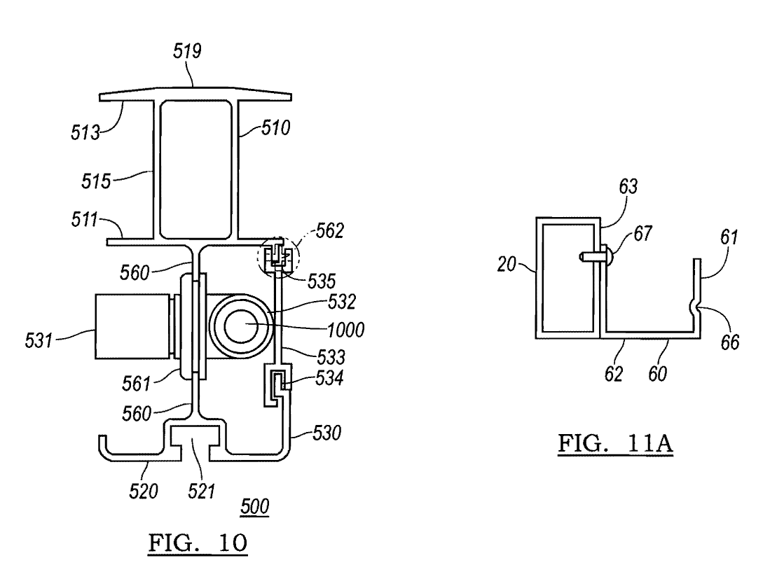

Notably, with the nuts 45 and bolts 40 tightened below a predetermined torque value, the bi-directional support system 10 can be easily folded to reduce space for shipping, as shown in FIG. 5B. Each lower support joist 20 is separated from the corresponding upper panel rails 30-n by nonconductive separation washers 24, preferably made of nylon, in order to prevent galvanic interaction between unlike materials. The nylon washer 24 is preferably about 118^{th} inch thick, although other materials and thicknesses may be used. The use of the nylon washer 24 at the intersection of lower support joist 20 and a corresponding upper support rail 30 facilitates the controlled rotation of these two elements with respect to each other. Controlled rotation is further facilitated if the nut 45 includes a nylon insert. The nylon insert helps to prevent the nut 45 from loosening during folding and unfolding of the support system 10.

Besides limiting galvanic interaction between unlike metals, nylon pieces are important for maintaining the precision of overall array alignment for support system 10. Precise positioning attained at the factory pre-assembly stage is more easily maintained through the use of the resilient nylon washers and other pieces. The nylon pieces serve to control the flexing of the support system 10 when it is put in the collapsed position and then later deployed into the full, open position. The use of the nylon pieces such as washer 24 is especially important in that additional adjustments do not have to be made in the field when the support system 10 is installed. This facilitates the quick installation that is so important to the present invention.

Previously-disclosed FIGS. 6 and 7 show the details of the panel holder or clip 100 attached to upper panel rail 30-n, with the length of panel 12 perpendicular the length of panel rail 30, as best seen in FIG. 3. However, other arrangements with different orientations of the length of panel 12 with respect to the length of the upper panel rail 30 are illustrative of the flexibility of the present inventive system. This flexibility is facilitated by the various arrangements of the different panel holders or clips 100, 100′ and 120, as depicted in FIGS. 1-7. The wide range of panel holders or clips 100, 100′ and 120 complement the ability of the present invention to provide a very precise pre-arrangement of the inventive support system 10 for easy installation of the panels at the final staging site.

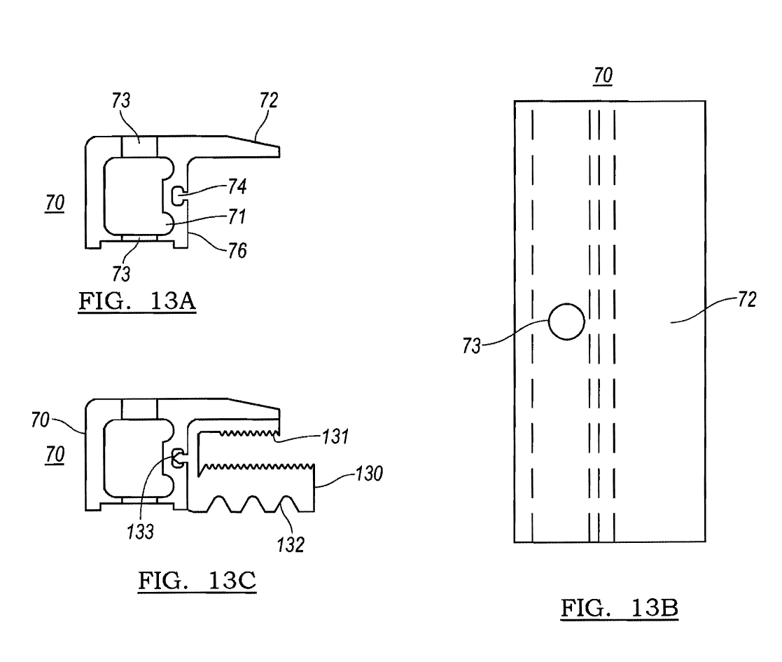

Specifically, once the upper panel rails 30 and the lower support joists 20 are deployed, the solar panels 12 (or other panel-like structures), either framed or unframed, can be fastened to the rails using friction clips 100, 100′ and 120. Various upper rail panel 30 configurations, such as those depicted in FIGS. 8, 9, 10 and 18 necessitate a wide range of panel holders or clips to be described infra. Accordingly, a wide range of new panel clips and gasket configurations are appropriate, as described infra. The object of all the new panel clip and gasket designs is the easy installation of panels in a manner that will remain secure under a wide variety of adverse circumstances.

Regarding panel clips 100, as shown in FIG. 3, many types of panel clips can be used as end or single-panel clips, and as intermediate or two-panel clips. Many panel clips are friction type. The friction type panel clips 100 encompass a wide variety of devices that hold or grip panel-like structures using a number of different methods. One is simple gravity. Another is the tightness of or pressure applied by the contact surfaces or arms of the insert or gasket encompassing a portion of the panel-like structure. More specifically, an insert or gasket 130 lining the panel clip 100 can create spring-like pressure through deformation of the gasket material. One example would be rubber or nylon teeth 131 extending from the arms of clip 100. Gaskets can be held to clips 100 using adhesive. The gaskets 130 used with holding clips 100, can be easily changed as needed, depending upon the position of the support system 10, and the configuration of the particular type of panel 12 supported thereby.

Preferably, the inserts or gaskets 130 (and all other gaskets described infra.) are made of a material that is physically and chemically stable, and electrically nonconductive. Furthermore, the gaskets 130 should be of an electrically resistant material and have good elasticity upon compression. Suitable materials, which can be employed include, but are not limited to, neoprene, butyl rubber, ethylene-propylene diene monomer (EPDM), chlorinated polyethylene (CPE) and a polytetrafluoroethylene (PTFE) material such as GORTEX® (a trademark of W. L. Gore & Associates, Inc.) or TEFLON® (a trademark of E. I. DuPont de Nemours & Company).

Most notably, the support system 10 of this invention allows for off-site assembly (at a convenient staging site) to precise engineering specifications, in that, once the support members are assembled, the bi-directional span can be folded or collapsed on itself, as shown with reference to FIG. 5, and then easily transported to the installation site. The support system 10 is then positioned and secured to the free-field ground rack, tracking unit, or other substrate via the tilt mounting bracket 16 (or equivalent structure) while still in the folded position. More specifically, after attaching one lower support joist 20 to one of the tilt mounting brackets 16, using a pair of tilt mounting bracket attachment bolts 240 (wedged between adjacent rails 30-2 and 30-3 in the folded position, as shown in FIGS. 5B and 5C) the bi-directional support system 10 is unfolded to the position of FIGS. 4A and the other lower support joist 20 is attached to the second bracket 16, via a second pair of tilt bracket bolts 240. This arrangement of support system 10 provides the capability of rapid, accurate deployment, requiring little skilled labor.

While the present inventive support system 10 has been previously described as being deployed on the tilt brackets (of FIG. 1), it is more likely that the support system 10 will be deployed on a wide variety of different substrates such as concrete pads or building roofs. In all situations, a precise measurement of the mounting site is taken, the array is manufactured at a factory and preassembled to make certain that it will fit precisely with the deployment site. Then, support system 10 is folded, shipped and deployed at the installation site. This process is essentially the same regardless of the installation site or the substrate that will support system 10. The purpose is to provide quick, simplified installation while maintaining high precision and structural standards.

The first step to rapid, inexpensive installation of solar panels 12 is the deployment of the support system 10 as summarized above, and elaborated upon in the three previously disclosed patent applications incorporated herein. However, deployment of the support system 10 is only part of the overall system installation. Placement of the solar panels on the support structure, and securing them thereto is also crucial. Likewise, the wiring of the solar panels is a necessary aspect that often requires the use of highly skilled labor and commensurate expenditure of funds. Accordingly, these aspects of solar panel installation must also be addressed.

FIGS. 8, 9 and 10 depict new types of upper panel rails 30 designated 300, 400, 500 (Thin Film Rail, Gravity Rest Rail, and Slide-In Rail, respectively) to be used in the same manner as upper support rails 30 in FIGS. 3-7. One key difference between these rails and those disclosed in the previously disclosed patent applications resides in the lower wiring portions 330, 430, 530 of the upper panel support rails 300, 400, 500, respectively. The modifications to the lower wiring section of each type of upper panel support rail are the same for each type of upper panel rail 300, 400, 500. The lower wiring sections 330, 430, 530 depicted are important in that they facilitate rapid, accurate wiring for installation of solar panels 12 once they are secured to the support system 10.

Lower wiring portions 330, 430, 530 are important since they are uniform for a wide range of upper rail panel sizes, shapes and panel clip configurations. This means that in a wide variety of different arrays or different panel types, and different panel clip arrangements, the wiring scheme remains the same. The uniform wiring scheme is designed to protect the long cable runs for the entirety of the array, as well as facilitating a rapid connection from each of the panels to the main cable. Exposure of any of the wiring to the elements is substantially limited by the overall structural arrangement of the lower wiring portions 330, 430, 530.

Protection of the main cable 1000, which normally receives the most abuse during installation, is a key feature of the present inventive wiring scheme. The main cable, which is particularly vulnerable because of its length and weight is held within an enclosed space, which is accessible on one side by a sliding panel, and on the other side only by apertures in the supporting wall, which are used to hold dedicated wiring fixtures. The result is that exposure of the entire wiring system to environmental hazards is minimized.

The upper tubular panel support portions 310, 410, 510 of all three upper support rail designs in FIGS. 8, 9 and 10 are also new refinements to the structures described in the previously-disclosed patent applications incorporated herein by reference. FIGS. 8, 9 and 10 are “cut away”, or sectional end views of new upper panel rails 300, 400 and 500, respectively. Each of the upper tubular support sections 310, 410, 510 functions in a similar manner to the upper portions of the upper panel rails 30, described in the previously-disclosed applications incorporated by reference.

However, there is a major structural distinction in the new designs of FIGS. 8, 9 and 10. In particular, the upper tubular panel support portions 310, 410, 510 are supported by central walls 360, 460, 560, respectively. This is a different structural arrangement than that of the previously-disclosed applications. This central wall structure (360, 460, 560) is particularly relevant to the lower wiring portions 330, 430, 530, as described infra.

Very often the most difficult aspect of installing solar panels is the wiring. Conventionally, it was necessary to employ the services of an electrician, at extremely high hourly rates. Even with professional handling of the wiring of individual panels and the overall connection of the array, protection of the wiring could be problematical. The present invention accommodates both easy electrical installation (with unskilled labor) and substantial protection of the necessary wire runs. Decreased installation time is also crucial to avoid damage to such substrates as roofs.

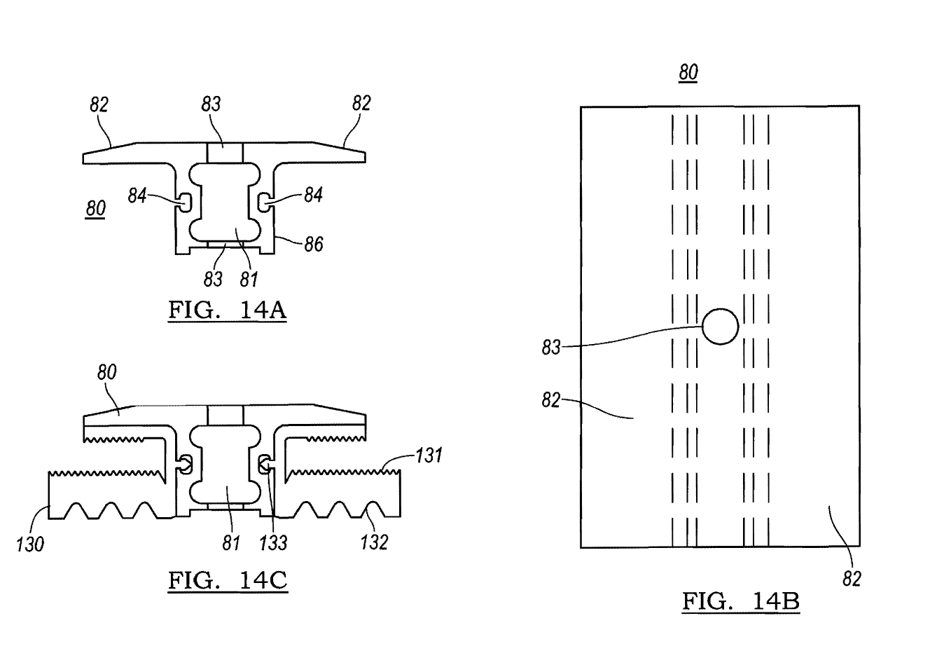

The accommodations to facilitate easily installed, yet secure, electrical connections are best explained with respect to FIG. 8. The same electrical connection arrangements are also found in FIGS. 9 and 10, which accommodate different panel connections. All views are sectional end views of the subject upper support rails. All of the depicted wiring structures 330, 430, 530 are uniform, and so designed to facilitate rapid installation and wiring of solar panels 12. With a clear, uniform wiring system, the level of skill needed for installation is substantially reduced.

In FIG. 8, upper panel rail 300 (also known as a Thin Film Rail) has an upper tubular panel support structure 310 with an upper surface 311 for supporting a panel or panel-like structure. It is noted that this version of upper panel rail 300 accommodates a thin film panel (not shown) which is connected to upper panel rail 300 using a panel clip (not shown) held by a fastener (not shown) inserted through an aperture (not shown) formed in thickened reinforcing section 312, part of upper surface 311. The embodiment of FIG. 8 is usually associated with thin films, and serves as an end piece in a panel array. However, with the proper panel clips and gaskets, upper panel rail 300 (also designated as Thin Film Rail) can also serve as an interior panel support. Likewise, upper panel rail (Thin Film Rail) 300 can support other types of panels.

Like the previously disclosed upper panel rails 30 in the prior applications incorporated herein by reference, upper panel rails 300, 400, 500 include bottom surfaces 320, 420, 520, that rest upon a lower support joist 20 (as depicted in FIGS. 6 and 7). There is also a T-slot channel 321 for a bolt connection to hold upper panel rail 300 to lower support joist 20. This T-slot channel 321 runs the entire length of upper panel rail 300, as is common with some of the upper panel rails previously disclosed.

Central support wall 360 connects the upper tubular panel support portion 310 to the bottom surface 320 which includes T-slot channel 321. As depicted in the drawings, central support wall 360 contains at least one aperture fixture or grommet 361. The fixture 361 accommodates passage of a quick connect plug 331 to obtain access to cable holder 332. The quick connect plug 331 is a standard electrical device used for making quick connections into a cable run. Once cable 1000 is in cable holder 332, the cable is pierced by, or otherwise made accessible to quick connect plug 331. Cable 1000 connects to quick connect plug 331 from the appropriate solar panel 12.

Access is provided to both cable 1000 and cable holder 332 by way of sliding access panel 333. Access panel 333 runs the entire length of upper panel rail 300, and is connected to the rest of the lower wiring portion 330 using upper connection slot 335 and lower connection slot 334. A retaining screw 362 is used at either end of the upper panel rail 300 to hold access panel 333 in place.

An aperture in central support wall 360 can be fabricated wherever appropriate for placement of aperture grommet 361 and quick connect plug 331. Performing of apertures can be done at the factory. Accordingly, a wide range of panel sizes and connection configurations can easily be accommodated with the present invention. The different electrical configurations must be accommodated in order to contain the different panel configurations that can be used with the upper panel rails 300, 400, and 500.

The lower wiring portions 430, 530, depicted in FIGS. 9 and 10, respectively, contain the same structures as those described with respect to lower wiring portion 330 in FIG. 8. Consequently, lower wiring portion 430 (including elements 420-462) in FIG. 9, and lower wiring portion 530 (containing elements 520-562) in FIG. 10 are identical to lower wiring portion 330 in FIG. 8. Accordingly, no additional description is necessary for an understanding of the lower wiring portions 430 and 530. This uniformity makes wiring of different panel types and configurations much easier, especially for unskilled labor.

Wiring of the overall panel array is facilitated by other aspects of the support system 10. In particular, FIGS. 11(A-C) depict a wire or cable trough 60 that is arranged along lower support joists 20. This arrangement provides a structure that accommodates wiring that runs parallel to the lower support joists 20. This structure keeps the wiring from loosely sagging from the solar panels 12 and upper panel rails 300, 400, 500. These cable troughs 60 can be used on upper panel rails 300, 400, 500, as well.

As depicted in FIGS. 11(A-C) cable or wire trough 60 is used to contain the otherwise sagging cables running from one upper panel rail 300 to another. Cable or wire trough 60 is attached to lower support joist 20 as depicted in FIG. 11A, so that the body of cable trough 60 extends outward from a lower support joist 20 located on the edge of the panel array. The body of cable trough 60 is constituted by a back wall 63 with a connecting aperture 67 for a screw connection to lower support joist 20. There is also a bottom wall 62, which can have a drain (not shown) if so desired. Front wall 61 also contains a support rib 66 to help prevent deformity of cable or wire trough 60 along the length of the lower support joist 20.

FIG. 11B depicts the location of cable or wire trough 60 with respect to the overall support system 10. The advantage of cable or wire trough 60 is that cables that would otherwise hang loosely from upper panel rails 300 are enclosed within the container constituted by cable or wire trough 60. Otherwise, the cables would sag, being exposed to accident and environmental factors. Further, the weight of the cables would cause additional strain on the cables. The cable trough 60 prevents this strain, as well as preventing the cables from being subjected to the stresses caused by the wind. Mounting the cable trough 60 is extremely easy, using pre-drilled apertures and simple metal screws. The presence of the cable or wire trough 60 makes installation easier since there is a place to put the cables rather than allowing them to constitute an impediment to further work on the panel array.

Control and placement of the electrical wiring is necessary to the overall protection of the panel array. It is also an important factor during installation to prevent accidents that may damage any of the wiring, a roof substrate, or the installer. To help prevent this, a wire holder 50, as depicted in FIGS. 12(A-C), can be placed either permanently or temporarily on the support system 10. One example of a placement technique is in those areas of the T-slot or channel 321 (on upper panel rail 300 in FIG. 8) that are not otherwise occupied with the connecting bolts 240. This means that most of the T-slot channel can be used for the placement of any number of wire holders 50. Wire holder 50 is preferably made of nylon. However, other semi-flexible materials can be used.

The easiest way to use the wire holder 50 is to simply slip it into the T-slot channel 321 at the bottom of an upper support rail 300. The wire holder 50 can be slid along this slot and will hold thereto by the virtue of four mounting prongs 52 located below the base 51 of the wire holder. Opposite the mounting prongs 52 on base 51 are a first annular arm 53 and a second annular arm 54. Both of these arms are reinforced by ribs 531 and 541, respectively. The first annular arm 53 has an outward extension 532, which extends roughly perpendicular to the direction of the arc formed by the first annular arm 53. The second annular arm 54 has a bi-directional extension 542, consisting of an inward portion 543, and an outward portion 544. The result is the open cup-like structure formed by extensions 532 and 542. This structure is convenient for holding wire while it is being pressed into the cavity between the annular portions of arms 52 and 53. The inward portion 543 of the bi-directional extension 542 on second annular arm 54 keeps the wire within the two arms 53, 54 once it has been forced inward. This also provides convenient operation during the installation process.

While the inward portion 543 holds the wire in wire holder 50, removal of the wire, if desired, is relatively easy. The flexible nature of first and second annular arms 53, 54 allows a user to simply pull them apart using outward extension 532 and outward portion 544 of the respective annular arms 53, 54. By pulling the two annular arms apart, the wire can easily be removed through the expanded opening.

It should be understood that wire holder 50 can also be used in other embodiments of upper panel rail 300. For example, the previously discussed upper panel rail 30 in FIG. 6 uses a C-shaped channel 34 as a wire trough. The four flexible mounting prongs 52 can be slipped into C-shaped channel 34 and held therein to provide additional wire holding capability, either permanent or temporary.

Quick, easy installation (by unskilled labor) is one of the benefits of the inventive embodiments disclosed. However, there is a drawback to most systems that permit easy installation of solar panels. In particular, conventional panel holders or clips very often do not hold the panels securely if the clips are configured for easy installation. As a result, sagging or other deformation by the panels, (whether due to gravity, environmental considerations, or accident) often cause panels to loosen in the clips and even cause disconnection and loss of the panels. The use of spacers between the panels can sometimes alleviate misalignment between adjacent panels but are often incapable of holding deformed panels in place, especially if those panels are at the edge of an array. Accordingly, the present application provides clips that can address possible deformation of the panels, and loosening from the clips, as well as maintaining ease of installation.

Quick, efficient and reliable installation of the panel array also includes ease of mounting and securing the panels 12 on the support system 10, once it has been deployed. Not only do the panels 12 have to be easily positioned on the support system 10, but the panels 12 must be easy to secure reliably. The requirements for the clips for holding devices to secure the panels vary with the overall size, thickness and materials constituting the panels.

A number of panel clips or holding devices (120, 145, 100′, 100) have already been disclosed in the prior applications. Despite the efficacy of these devices, certain types of panels have a tendency to sag, flex, or otherwise deform, due to gravity or environmental conditions. The stresses caused by this deformation are transmitted through the panel clips or holding devices (100, 120, 145), causing the clips to shift and otherwise deform themselves. The result is very often slippage or even loss of the panel from the panel clip. Conventional means for countering this tendency have proven unsatisfactory. Either the panel clips continue to fail under certain circumstances, or the installation process becomes unduly long and tedious, thereby increasing the expense of the solar panel array.

FIGS. 13(A-C) and 14(A-C) depict two new panel holders or clips 70, 80. Both of these clips 70, 80 include tubular structures 71, 81, respectively, to provide reinforcement and prevent the kind of flexing that results in panel loosening, misalignment and loss. Clip 70 is configured to hold a single panel 12, while clip 80 is configured to hold two panels 12, one on either side. With both clips 70, 80, the held panels 12 receive the benefits of tubular stiffening structures 71, 81, thereby limiting panel movement by preventing deformation of clips 70, 80.

Both panel clips 70, 80 have a back wall 76, 86 for abutting the edge of the panel 12, and at least one holding structure 72, 82 extending over the face of the panel 12. Both types of panel clip 70, 80 contain apertures 73, 83 so that bolts or other fasteners can hold the panel clips to the top of an upper panel rail (30, 300, 400, 500).

It should be clear that the new panel clips 70, 80 are meant for the thin film rail 300, as depicted in FIG. 8. However, both of these clips 70, 80 can be sized to be very serviceable on a wide variety of panels 12 and upper panel rail 30 configurations such as those depicted in the subject applications previously incorporated by reference (such as FIG. 6). Like the rest of the support system 10, the panel clips 70, 80 are pre-drilled to receive the appropriate fastener. Likewise, the proper locations on upper panel rails 30 are also pre-drilled to receive the same fastener.

In order to properly secure the panels 12, insert gaskets or liners are necessary on the panel clips 70, 80. This is true whether using the new panel clips 70, 80, or using the previously-disclosed panel-holding devices. The gaskets can be held to the panel clips 70, 80 using adhesive. FIGS. 13C and 14C depict clips 70, 80 with U-shaped gaskets 130. This is one preferred gasket arrangement. U-shaped gaskets 130 are preferably made of a sixty-durometer material and can be EPMD material ASTMD 2000. However, other suitable materials can also be used.

The U-shaped gasket 130 has two types of teeth. The first type 131 is used to hold the solar panels 12, and is relatively fine. Larger teeth 132 are used to help grip the underlying upper support rail. The gasket 130 can be held to panel clips 70, 80 by means of an adhesive. However, the protrusion 133 can be inserted into cavities 74, 84 to mechanically hold gasket 130 to the respective vertical back walls 76, 86 of clips 70, 80, respectively.

In the alternative, the gaskets 130 can be held by way of friction fit, in a U-shaped clip. One such example would be the upper panel rail 500 (Slide In Rail), as depicted in FIG. 10. The upper tubular structure 510 includes lower horizontal surfaces 511, upper horizontal surfaces 513, and connecting vertical walls 515. This forms a configuration in which there are three possible surfaces on each side to receive gaskets to help hold a solar panel. The strength of upper tubular panel support structure 510 is insured by upper connecting structure 519, which completes the tubular enclosure of the overall structure. The upper panel rail 500 admits to a wide variety of different panel sizes since a wide variety of different gasket configurations can be added at the option of the solar array designer. The other upper panel rail structures in FIGS. 8 and 9 require distinct panel clip and gasket arrangements, different from those previously described in connection with FIGS. 13(A-C) and 14(A-C).

Another example of a gasket configuration for use with another variation of upper support rail 30, such as upper panel rail 400 (Gravity Rest Rail) of FIG. 9 is the L-shaped gasket 140 as depicted in FIG. 15, and the straight gasket 150 of FIG. 16. Preferably, the subject gaskets 140, 150 are attached to either panel clips 70, 80 by means of a standard adhesive. Deployment of gaskets 140, 150 is depicted in FIG. 18. It is noted that this structure contains an upper tubular panel support portion 410 for supporting solar panels 12, which is similar to the arrangement depicted in FIG. 9. The riser structure 418 has vertical walls 415 and horizontal walls 411 for accommodating an L-shaped gasket 140. There is also an aperture in the top surface 419 to receive a fastener, such as 95, as depicted in FIG. 18.

The security of solar panel 12 depends, to some extent, on gravity, the tooth configuration of L-shaped gasket 140, and the tight connection from cap 90, as depicted in FIG. 17. Cap 90 has an upper surface with an aperture 91 for receiving a fastener (95, as depicted in FIG. 18) at a relatively horizontal portion of the upper surface. The edges of the upper surface of cap 90 are curved, as depicted in FIG. 17. Also, the lower surface has two concavities 92. These are sized and configured to receive protrusions 413 on top surface 419 of the upper panel rail 400 (Gravity Rest Rail) depicted in both FIGS. 18 and 9. The interface of protrusions 413 with cavities 92 further secures cap 90 to the top of the gravity rest rail riser structure 418 in FIG. 18.

The L-shaped gasket 140 further facilitates a secure connection with solar panel 12 by virtue of the tooth structure of gasket 140. In particular, the teeth 141 that interface with the edge of the panel 12 have a 45° angle between the edges of the teeth. Further, these teeth are somewhat longer than the teeth 142 on the other side of the gasket. Teeth 142 are arranged so that the angle between adjacent tooth edges is 90°. This better facilitates a gentle hold on the surface of the panel 12. The tooth structure 151 of straight gasket 150 is configured so that the angle between adjacent tooth edges is 90°. This facilitates a strong grip based upon the pressure applied by the tightening of fastener 95 through cap 90.

It should be understood that the slide-in rail structure 500, as depicted in FIG. 10 can use the U-shaped gaskets 130, modified for the correct dimensions. Likewise, a gasket configuration similar to that found in FIG. 18 can also be applied to the upper panel rail 500 (Slide-In-Rail) of FIG. 10.

While a number of embodiments have been described as examples of the present invention, the present invention is not limited thereto. Rather, the present invention should be construed to include every and all modifications, permutations, variations, adaptations, derivations, evolutions and embodiments that would occur to one having skill in this technology and being in possession of the teachings of the present application. Accordingly, the present invention should be construed as being limited only by the following claims.

We claim:

1. A wiring and panel support system in a bi-directional solar panel support matrix having lower support joists and upper panel rails, said upper panel rails comprising:
a) an upper panel support portion; and,
b) a lower wiring portion;
wherein said lower wiring portion remains substantially uniform for a plurality of different upper panel clip portion arrangements.

2. The system of claim 1, wherein said upper panel support portion comprises a first tubular structure.

3. The system of claim 2, wherein said upper panel support portion comprises a flat surface configured to support an external panel.

4. The system of claim 2, wherein said upper panel support portion comprises two lower panel support surfaces.

5. The system of claim 4, wherein said upper panel support portion comprises two holding structures spaced from said lower panel support surfaces to hold an upper edge of said external panel.

6. The system of claim 3, further comprising at least a lower serrated gasket.

7. The system of claim 6, further comprising an upper serrated gasket.

8. The system of claim 7, further comprising a holding cap arranged to hold said upper serrated gasket to said external panel.

9. The system of claim 8, wherein said holding cap is connected to said upper panel support portion with a screw fastener.

10. The system of claim 2, wherein said lower wiring portion comprises a second tubular structure connected to said first tubular structure.

11. A wiring system in a bi-directional solar panel support matrix, having lower support joists and upper panel rails, said upper panel rails comprising:
a) an upper panel support portion; and
b) a lower wiring portion comprising:
i) a lower support structure interfacing with an upper surface of a corresponding said lower support joist;
ii) a central connecting wall bridging said lower support structure and said upper panel support portion; and
iii) a sidewall extending from said lower support structure to said upper support portion to define a cable channel with said central connecting wall.

12. The wiring system of claim 11, wherein said sidewall comprises a removable panel exposing an interior of said cable channel.

13. The wiring system of claim 12, wherein said central connecting wall comprises at least one aperture, providing access to said cable channel.

14. The wiring system of claim 13, wherein said lower support structure comprises a bolt-head channel.

15. The wiring system of claim 14, wherein said bolt-head channel comprises a T-shaped slot.

16. The wiring system of claim 11, wherein said upper panel support portion comprises a tubular structure.

17. The wiring system of claim 16, wherein said upper panel support portion comprises a flat upper surface.

18. The wiring system of claim 17, wherein said upper support panel portion comprises two flat panel support surfaces divided by a middle portion of said tubular structure.

19. The wiring system of claim 18, wherein said upper panel support portion further comprises upper support structures spaced from said lower panel support surfaces to hold external panels.

20. The wiring system of claim 18, further comprising a holding cap attachable to said tubular structure to hold said external panels.

21. The wiring system of claim 20, wherein said holding cap is attachable with a threaded connector into a top surface of said middle portion of said tubular structure separating said two panel support surfaces.

22. A method of wiring a solar panel array supported by a bi-directional support matrix having lower support joists and upper panel rails arranged to hold said solar panels, said upper panel rails having a set of first sidewalls to form a first interior space, and a central connecting wall with a second sidewall to form a second interior space, said wiring method comprising the steps of:
a) placing at least one electrical lead from a solar panel into at least said second interior space;
b) extending at least one electrical cable along a length of said upper panel rail in said second interior space; and,
c) connecting said at least one lead to said cable.

23. The method of claim 22, wherein step (c) of connecting comprises the substep of:
i) forming at least one aperture through said central connecting wall.

24. The method of claim 23, wherein step (c) of connecting further comprises the substep of:
ii) placing a fixture through said at least one aperture.

25. The method of claim 24, wherein step (c) of connecting further comprises the additional sub step of:
iii) running said at least one electrical wire through said fixture to connect to said at least one cable.

26. The method of claim 24, wherein a connection between said fixture and said at least one cable facilitates electrical connection between said at least one electrical wire and said at least one cable.

27. In a bi-directional solar panel support matrix, having lower support joists and upper panel rails, said upper panel rails comprising a lower wiring section having at least a first tubular structure; and, an upper panel support portion having a second tubular structure including at least one surface to support a solar panel.

28. The upper panel rail of claim 27, further comprising at least two panel support surfaces, each said panel support surface being separated by an upper portion of said second tubular structure.

29. The upper panel rail of claim 28, further comprising two upper extensions supported above said tubular structure and over said panel support surfaces, and spaced to accommodate solar panels.

30. The upper panel rail of claim 29, further comprising a holding cap extending parallel to and over a portion of said panel support surfaces, and connectible to said upper support rail at said portion of said second tubular structure separating said two panel support surfaces.

31. The upper panel rail of claim 30, further comprising a threaded fastener to hold said holding cap to said portion of said second tubular surface separating said two panel support surfaces.

32. The upper panel rail of claim 31, further comprising serrated gaskets on at least a portion of the corresponding said panel support surfaces.

33. The upper panel rail of claim 32, further comprising at least one additional gasket between said holding cap and at least a portion of said corresponding solar panel.

34. The upper panel rail of claim 33, further comprising at least one additional gasket positioned 90° from one of said panel support surfaces.

35. A panel clip configured to hold a panel to an upper panel rail in a bi-directional panel support array, said panel clip comprising:
a) a hollow tubular support structure arranges to be attached to said upper panel rail; and
b) at least one upper holding structure spaced from an upper surface of an upper panel rail on which said panel clip is mounted so that a panel fits between the upper holding structure and the upper surface of the upper panel rail.

36. The panel clip of claim 35, further comprising a second holding structure extending opposite of said first upper holding structure.

37. The panel clip of claim 35, further comprising two apertures in said tubular support structure to accommodate a connector holding said panel clip to said upper surface to said upper panel rail.

38. The panel clip of claim 35, further comprising a U-shaped gasket arranged beneath said upper holding structure and on said upper surface of said upper panel rail.

39. The panel clip of claim 38, wherein said U-shaped gasket has two saw-tooth surfaces of a first type facing each other on an interior of said U-shape.

40. The panel clip of claim 39, wherein said U-shaped gasket has a second saw-tooth configuration on an exterior surface of said U-shaped gasket facing said upper surface of said upper panel rail.

41. The panel clip of claim 38, where said U-shaped gasket comprises a connection prong interfacing with a complementary concavity on said panel clip.

42. The panel clip of claim 40, wherein said first saw-tooth configuration is smaller than said second saw-tooth configuration.

43. A wiring and panel support system in a bi-directional solar panel support matrix having lower support joists and upper panel rails, and a wiring holding system, said wiring holding system comprising:
a) a T-shaped connection channel formed into a bottom surface of said upper panel rail; and,
b) a wiring clip having a connection portion configured to fit into said T-shaped channel.

44. The system of claim 43, wherein said wiring holding system further comprises a C-channel formed in a lower portion of said panel rail and extending along a length of said upper panel rail, said C-channel being sized and configured to receive said connection portion of said wiring clip.

45. The system of claim 43, wherein said wire holding system further comprises a U-shaped external trough connected to at least one lower support joist and extending along a length of said lower support joist.

46. The system of claim 43, wherein said wire holding clip has a semicircular wire holding portion connected to the connection portion.

47. The system of claim 46, wherein said wiring clip comprises an opening in said semicircular wiring portion, said opening having a straight retaining portion extending inward from one semicircular portion of said wiring holding portion of said wiring clip.

48. The system of claim 46, wherein said wire clip connection portion comprises a T-shaped profile ending in a truncated cone.

49. The system of claim 48, wherein said connection portion is divided longitudinally into four separate, flexible sections to facilitate connection.
